(19) United States
(12) Patent Application Publication
(10) Pub. No.: US 2026/0173293 A1
(43) Pub. Date: Jun. 18, 2026

(54) DISPLAY APPARATUS

(71) Applicant: SAMSUNG ELECTRONICS CO., LTD., Suwon-si (KR)

(72) Inventors: Hyunyong CHOI, Suwon-si (KR); Daesu CHOI, Suwon-si (KR); Seungjae KIM, Suwon-si (KR); Jisu KIM, Suwon-si (KR); Kwangjae LEE, Suwon-si (KR); Yousub LEE, Suwon-si (KR)

(73) Assignee: SAMSUNG ELECTRONICS CO., LTD., Suwon-si (KR)

(21) Appl. No.: 19/535,807

(22) Filed: Feb. 10, 2026

Related U.S. Application Data
(63) Continuation of application No. PCT/KR2024/007955, filed on Jun. 11, 2024.

(30) Foreign Application Priority Data
Aug. 22, 2023 (KR) 10-2023-0110179

(51) Int. Cl. H05K 7/14; G02F 1/1333; H05K 7/02; H05K 7/12; H05K 7/18; H10H 29/85; H10K 59/18

(52) U.S. Cl. CPC H05K 7/1414; H05K 7/026; H05K 7/12; H05K 7/1417; H05K 7/183; H10H 29/8506; G02F 1/13336; H10K 59/18

(57) ABSTRACT

A display apparatus including a levelness-adjusting unit to adjust a difference in positions of a first display module and a second display module that are adjacent to each other. The levelness-adjusting unit includes: a gap-adjusting part to move joining portions, where the first display module and the second display module come into contact with each other, between a first position in which the joining portions come into close contact, and a second position in which the joining portions are spaced apart, according to the rotation direction of a pinion engaged with a rack gear; and a front-and-back levelness-adjusting part for adjusting the difference in positions of the joining portions in the forward and backward direction.

### CROSS-REFERENCE TO RELATED APPLICATION

This application is a continuation application, under 35 U.S.C. § 111(a), of international application No. PCT/KR2024/007955, filed Jun. 11, 2024, which claims priority under 35 U. S. C. § 119 to Korean Patent Application No. 10-2023-0110179, filed Aug. 22, 2023, the disclosures of which are incorporated herein by reference in their entireties.

### TECHNICAL FIELD

The disclosure relates to a display apparatus.

### BACKGROUND ART

In recent years, display apparatuses have become increasingly large with a plurality of display modules, including display panels, arranged together to form a large screen.

Large displays, for example, those of 100 inches or more, have limitations in transportation and installation. Therefore, rather than realizing a large display with a single display, a display that combines divided displays into a single display apparatus is being developed.

### DISCLOSURE

### Technical Problem

An aspect of the present disclosure provides a display apparatus in which divided display modules may be easily installed.

Technical tasks to be achieved in this document are not limited to the technical tasks mentioned above, and other technical tasks not mentioned will be clearly understood by those skilled in the art from the description below.

### Technical Solution

A display apparatus according to an embodiment of the present disclosure includes a level difference adjustment portion configured to adjust a level difference between a first display module and a second display module adjacent to each other, wherein the level difference adjustment portion comprises a gap adjustment portion configured to move a joint portion, at which the first display module and the second display module are in contact, between a first position for close contact and a second position for spacing apart, in response to direction of rotation of a pinion engaging with a rack gear; and a front-to-back level difference adjustment portion configured to adjust a front-to-back direction level difference of the seam.

A display apparatus according to an embodiment may include a pair of rail frames installed on a wall spaced apart vertically, a first display module and a second display module movably supported on the pair of rail frames and contactable with each other, and a level difference adjustment portion configured to adjust a level difference between the first display module and the second display module, wherein the level difference adjustment portion includes a gap adjustment portion configured to adjust a gap between the seams where the first display module and the second display module are in contact, and the gap adjustment portion includes a rack gear provided on the first display module, and a pinion provided on the second display module to engage with the rack gear and which, depending on a direction of rotation, brings the first display module and the second display module into contact or further apart.

A display apparatus according to an embodiment may include a level difference adjustment portion configured to adjust a level difference between a first display module and a second display module adjacent to each other, wherein the level difference adjustment portion comprises: a gap adjustment portion configured to move a seam, along which the first display module and the second display module are in contact with each other, between a first position while the first display module and the second display module are brought into close contact with each other and a second position in which the seam are spaced apart from each other, based on a direction of rotation of a pinion engaging with a rack gear; and a front-to-back level difference adjustment portion configured to adjust a front-to-back direction level difference of the seam.

### DESCRIPTION OF DRAWINGS

FIG. 1 illustrates a display apparatus according to an embodiment.

FIG. 2 illustrates a rear view of the display apparatus according to an embodiment.

FIG. 3 is an exploded perspective view of a gap adjustment portion according to an embodiment.

FIG. 4 is an assembly view of the gap adjustment portion according to an embodiment.

FIG. 5 is a view illustrating an operational state of the gap adjustment portion according to an embodiment.

FIG. 6 is a cross-sectional view taken along line A-A′ of FIG. 4 according to an embodiment.

FIG. 7 illustrates a coupling relationship of a stopper member according to an embodiment.

FIG. 8 illustrates a position regulating member in a case where contact of a seam of first and second display modules is allowed according to an embodiment.

FIG. 9 illustrates a position regulating member in a case where contact of the seam of first and second display modules is not allowed according to an embodiment.

FIG. 10 is a perspective view illustrating an up-and-down level difference adjustment portion according to an embodiment.

FIG. 11 is an exploded perspective view of the up-and-down level difference adjustment portion according to an embodiment.

FIG. 12 is a partially cutaway view of the up-and-down level difference adjustment portion according to an embodiment.

FIG. 13 is a view illustrating an operational state of the up-and-down level difference adjustment portion according to an embodiment.

FIG. 14 is an exploded perspective view of a wheel unit according to an embodiment.

FIG. 15 is a cross-sectional view of the wheel unit according to an embodiment.

FIG. 16 is a view illustrating an anti-separation member according to an embodiment.

FIG. 17 illustrates a cross-sectional view of the anti-separation member coupled to the wheel unit according to an embodiment.

FIG. 18 illustrates the travel stopper installed on the rail frame according to an embodiment.

FIG. 19 illustrates a cross-section of the travel stopper coupled to the rail frame according to an embodiment.

FIG. 20 illustrates a front-to-back adjustment member according to an embodiment.

### DETAILED DESCRIPTION OF THE EMBODIMENTS

Various embodiments of the present document and terms used therein are not intended to limit the technical features described in this document to specific embodiments, and should be understood to include various modifications, equivalents, or substitutes of the corresponding embodiments.

In connection with the description of the drawings, similar reference numerals may be used for similar or related components.

The singular form of a noun corresponding to an item may include one or a plurality of the items unless clearly indicated otherwise in a related context.

In the disclosure, phrases, such as “A or B”, “at least one of A and B”, “at least one of A or B”, “A, B or C”, “at least one of A, B and C”, and “at least one of A, B, or C” may include any one or all possible combinations of the items listed together in the corresponding phrase among the phrases.

The term of “and/or” includes a plurality of combinations of relevant items or any one item among a plurality of relevant items.

It will be understood that, although the terms “first”, “second”, “primary”, “secondary”, etc., may be used herein to describe various elements, but elements are not limited by these terms. These terms are only used to distinguish one element from another element. For example, without departing from the scope of the disclosure, a first element may be termed as a second element, and a second element may be termed as a first element.

When an element (e.g., a first element) is referred to as being “(functionally or communicatively) coupled” or “connected” to another element (e.g., a second element), the first element may be connected to the second element, directly (e.g., wired), wirelessly, or through a third element.

It will be understood that when the terms “includes”, “comprises”, “including”, and/or “comprising” are used in the disclosure, they specify the presence of the specified features, figures, steps, operations, components, members, or combinations thereof, but do not preclude the presence or addition of one or more other features, figures, steps, operations, components, members, or combinations thereof.

When a given element is referred to as being “connected to”, “coupled to”, “supported by” or “in contact with” another element, it is to be understood that it may be directly or indirectly connected to, coupled to, supported by, or in contact with the other element. When a given element is indirectly connected to, coupled to, supported by, or in contact with another element, it is to be understood that it may be connected to, coupled to, supported by, or in contact with the other element through a third element.

It will also be understood that when an element is referred to as being “on” another element, it may be directly on the other element or intervening elements may also be present.

A display module may include a display panel. The display panel may be one of a flat panel display panels and may be arranged with a plurality of inorganic light-emitting diodes (inorganic LEDs), each of which is 100 micrometers or less. Compared to liquid crystal display (LCD) panels that require a backlight, micro LED display modules may provide better contrast, response time, and energy efficiency. Both organic light-emitting diodes (OLEDs) and micro LEDs, which are inorganic light-emitting elements, are energy efficient, but micro LEDs may have higher brightness, luminous efficiency, and longer lifetime than OLEDs. A micro LED may be a semiconductor chip capable of emitting light on its own when power is supplied. Micro LEDs have a fast response time, low power consumption, and high luminance. Specifically, micro LEDs are more efficiency in converting electricity into photons compared to conventional LCDs or OLEDs. This may mean they have a higher “brightness per watt” compared to conventional LCD or OLED displays. Accordingly, micro LEDs may produce the same brightness with about half the energy compared to conventional LEDs (whose width, length, and height each greater than 100 μm) or OLEDs. In addition, micro LEDs may achieve high resolution, superior color, contrast, and brightness, enabling accurate representation of a wide range of colors, and enabling clear screens even outdoors in bright sunlight. Furthermore, micro LEDs may also be resistant to burn-in phenomena and generate less heat, ensuring a long lifespan without deformation.

The micro LEDs may have a flip-chip structure in which anode and cathode electrode terminals are formed on the same first surface, and a light-emitting surface is formed on a second surface located on an opposite side of the first surface on which the electrode terminals are formed.

A glass substrate may have a thin film transistor (TFT) layer, on which a TFT circuit is formed, on a front surface, and a drive circuit for driving the TFT circuit on a rear surface. The TFT circuit may drive a plurality of pixels disposed on the TFT layer.

The front surface of the glass substrate may be divided into an active region and an inactive region. The active region may correspond to a region occupied by the TFT layer on the front surface of the glass substrate, and the inactive region may be a region excluding the region occupied by the TFT layer on the front surface of the glass substrate.

An edge region of the glass substrate may be the outermost edge of the glass substrate. In addition, the edge region of the glass substrate may be a remaining region excluding the region in which the circuit of the glass substrate is formed. In addition, the edge region of the glass substrate may include a side surface of the glass substrate, a portion of the front surface of the glass substrate and a portion of the rear surface of the glass substrate adjacent to the side surface thereof. The glass substrate may be formed in a quadrangle type. Specifically, the glass substrate may be formed in a rectangle or a square shape. The edge region of the glass substrate may include at least one of four sides of the glass substrate.

A display module may include a glass substrate on which a plurality of LEDs are mounted and side wiring is formed. Such a display module may be applied as a single unit to wearable devices, portable devices, handheld devices, and various electronic products or electrical equipment that require a display, and may be applied to display devices such as monitors for personal computers (PCs), high-resolution televisions (TVs) and signage (or, digital signage), electronic displays, or the like, through a plurality of assembly arrangements in a matrix type.

Hereinafter, various embodiments according to the present disclosure will be described in detail with reference to the accompanying drawings.

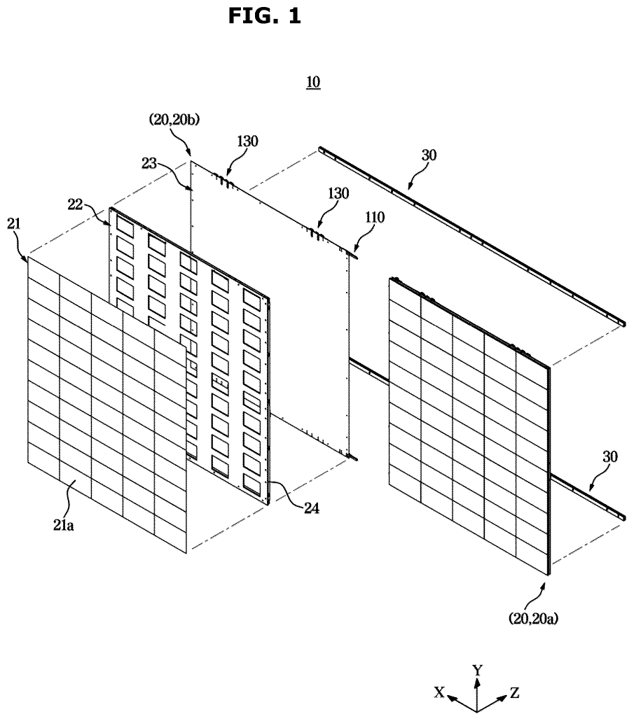

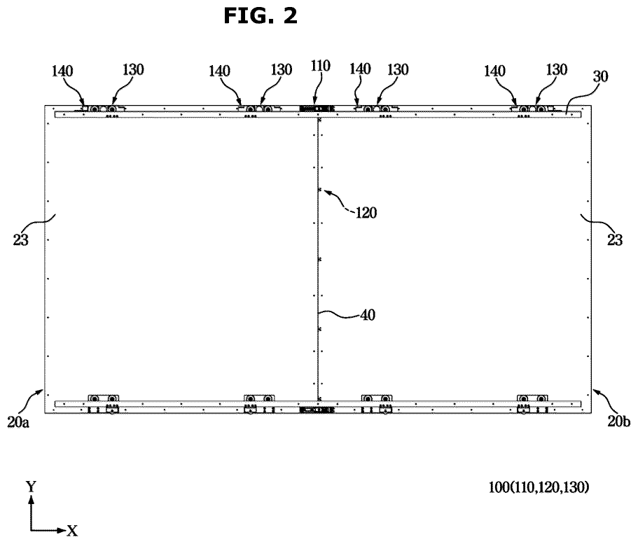

FIG. 1 is a view illustrating a display apparatus according to an embodiment. FIG. 2 is a rear view illustrating the display apparatus according to an embodiment.

As shown in FIGS. 1 and 2, a display apparatus 10 may include a plurality of display modules 20 disposed adjacent to each other.

Each of the plurality of display modules 20 may include a display panel 21 configured to display an image, a frame 22 configured to support the display panel 21, and a rear cover 23 configured to support a rear surface of the frame 22.

The display panel 21 may be arranged such that a plurality of panels 21a form rows and columns. Each of the plurality of panels 21a may include a substrate and an LED or a micro LED including a plurality of inorganic light-emitting elements mounted on the substrate. In addition, the plurality of panels 21a may include a liquid crystal panel or an organic display panel.

The display panel 21 may be coupled to the frame 22. The display panel 21 may be installed on the frame 22 by means of various methods, such as magnetic force using a magnet, a mechanical fitting structure, adhesion, or the like. The frame 22 may be provided as a composite panel with a low coefficient of thermal expansion and high rigidity.

A reinforcing frame 24 for increasing rigidity of the frame 22 may be installed on an edge of the frame 22. The reinforcing frame 24 may be interposed between the frame 22 and the rear cover 23.

Such plurality of display modules 20 may be installed on a rail frame 30 that is installed on a wall. The rail frame 30 may include a pair installed to be spaced apart from each other in an up-and-down direction on the wall. The plurality of display modules 20 may be installed with their upper and lower sides each supported by the pair of rail frames 30.

While an example in which two adjacent display modules 20 are disposed adjacent to each other is described below, the number of display modules is not limited thereto.

The plurality of display modules 20 may include a first display module 20a and a second display module 20b.

With the first display module 20a seated on the pair of rail frames 30, the second display module 20b may be seated on the pair of rail frames 30.

The first display module 20a and the second display module 20b may move along the pair of rail frames 30 in a left-to-right direction (X).

The display apparatus 10 according to an embodiment of the present disclosure may include a level difference adjustment portion 100 for adjusting a level difference (or step) between the first display module 20a and the second display module 20b, which are disposed adjacent to each other.

When the first display module 20a and the second display module 20b are disposed adjacent to each other, a seam 40, which is a boundary region, may be formed between the first display module 20a and the second display module 20b.

The level difference adjustment portion 100 may include a gap adjustment portion 110 that moves a seam 40, where the first display module 20a and the second display module 20b contact, in a direction of moving away from or closer to each other.

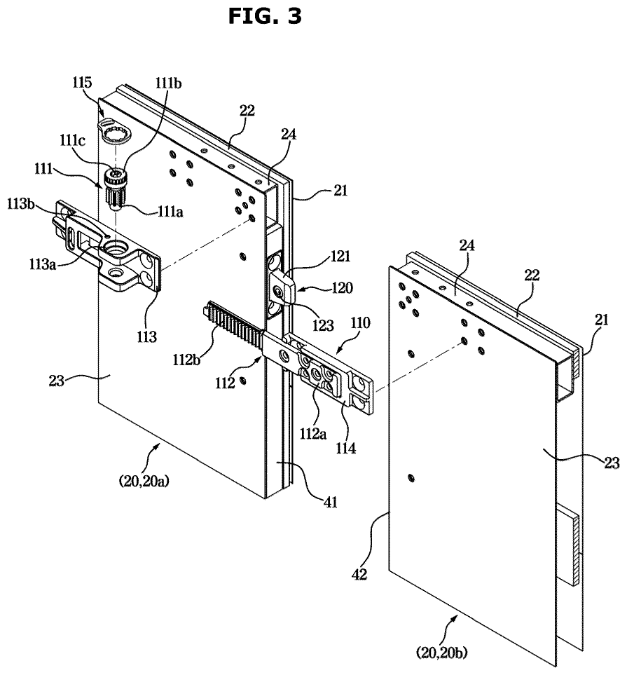

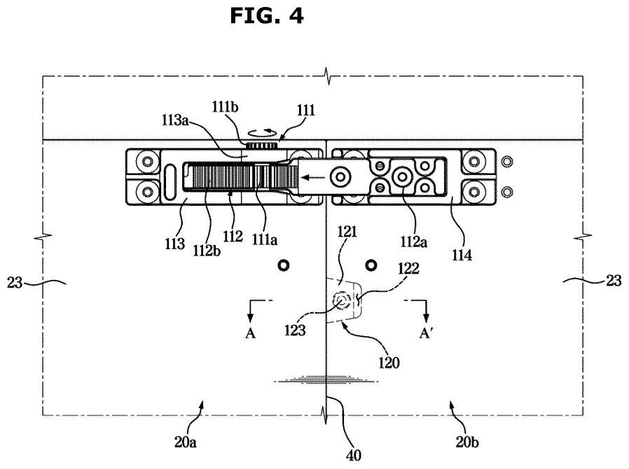

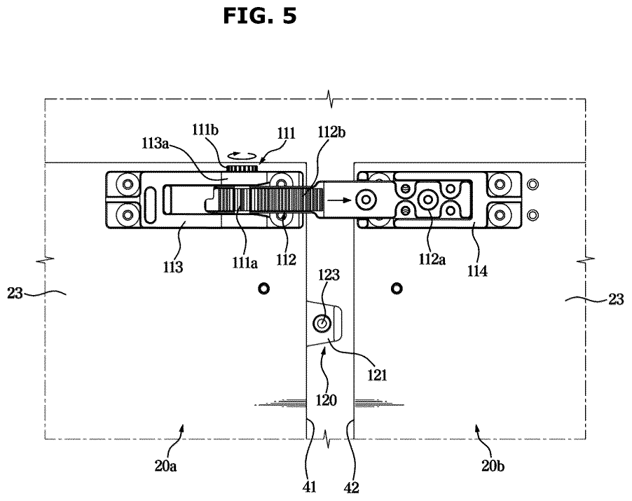

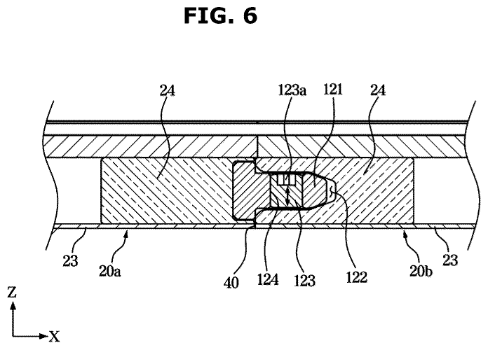

FIG. 3 is an exploded perspective view of a gap adjustment portion according to an embodiment, FIG. 4 is an assembly view of the gap adjustment portion according to an embodiment, FIG. 5 is a view illustrating an operational state of the gap adjustment portion according to an embodiment, and FIG. 6 is a cross-sectional view taken along line A-A′ of FIG. 4.

Referring to FIGS. 3 to 6, the gap adjustment portion 110 may move the seam 40 of the first display module 20a and the second display module 20b in a direction of moving away from or closer to each other.

The gap adjustment portion 110 may move the seam 40 of the first display module 20a and the second display module 20b between a first position that moves the seam 40 of the first display module 20a and the second display module 20b closer to each other, as shown in FIG. 4, and a second position that moves the seam 40 of the first display module 20a and the second display module 20b further apart from each other, as shown in FIG. 5.

The gap adjustment portion 110 may be coupled to a rear surface of the display apparatus 10. The gap adjustment portion 110 may be coupled to the rear cover 23 that forms the rear surface of the display apparatus 10. The gap adjustment portion 110 may be positioned adjacent to an upper end of the rear surface of the display apparatus 10 for ease of operation by a user.

The gap adjustment portion 110 may include a pinion 111 coupled to a rear surface of the first display module 20a, and a rack gear 112 coupled to a rear surface of the second display module 20b.

The pinion 111 and the rack gear 112 of the gap adjustment portion 110 may be installed to engage with each other. Depending on a direction of rotation of the pinion 111, the rack gear 112 may be reciprocated in the left-to-right direction. When the pinion 111 rotates in one direction to move the rack gear 112 in a pulling direction, the first display module 20a and the second display module 20b may move in a direction that brings them closer to each other. When the pinion 111 rotates in the other direction opposite the one direction to move the rack gear 112 in a pushing direction, the first display module 20a and the second display module 20b may move in a direction of moving away from each other.

The gap adjustment portion 110 may include a first bracket 113 on which the pinion 111 is rotatably mounted, and a second bracket 114 to which the rack gear 112 is coupled.

The first bracket 113 may be coupled to the rear surface of the first display module 20a, and the second bracket 114 may be coupled to the rear surface of the second display module 20b. The first bracket 113 and the second bracket 114 may each be coupled to the reinforcing frame 24 of the corresponding display module 20 via a fastening member, such as a bolt.

The pinion 111 may include a shaft portion 111a having gear teeth that engage with the rack gear 112, and a head portion 111b having a larger diameter than the shaft portion 111a. The shaft portion 111a may be rotatably supported by a shaft support portion 113a provided on the first bracket 113. The head portion 111b may protrude upwardly from the shaft support portion 113a. The head portion 111b may include a wrench groove 111c to which a tool for rotationally manipulating the pinion 111 is coupled. When an operator rotates the tool clockwise or counterclockwise with the tool inserted into the wrench groove 111c, the rack gear 112 engaged with the pinion 111 may reciprocate in the left-to-right direction (X).

The rack gear 112 may be coupled to the second bracket 114. A coupling portion 112a provided on one side of the rack gear 112 may be fixedly installed on the second bracket 114, and a rack gear portion 112b provided on the other side may extend toward the pinion 111 installed on the first bracket 113. The rack gear portion 112b may engage with the gear teeth provided on the shaft portion 111a of the pinion 111.

The level difference adjustment portion 100 may include a front-to-back level difference adjustment portion 120 for adjusting the front-to-back direction (Z) level difference of the seam 40 where the first display module 20a and the second display module 20b are in contact. The front-to-back level difference adjustment portion 120 may be disposed spaced apart by a predetermined gap along the up-and-down direction (Y) of the display apparatus 10. The front-to-back level difference adjustment portion 120 may be installed on the reinforcing frame 24 installed on one side edge of the display module 20.

The front-to-back level difference adjustment portion 120 may be exposed to an outside of the display apparatus 10 or concealed from view from the outside by an operation of the gap adjustment portion 110.

The front-to-back level difference adjustment portion 120 may not be exposed to the outside in a state in which the seam 40 of the first display module 20a and the second display module 20b are in contact, as shown in FIG. 4, and may be exposed to the outside in a state in which the seam 40 of the first display module 20a and the second display module 20b are spaced apart, as shown in FIG. 5. An operator may manipulate the front-to-back level difference adjustment portion 120 exposed to the outside from the front side of the display apparatus 10.

The front-to-back level difference adjustment portion 120 may be provided on joint surfaces 41 and 42 that form the seam 40 of the first display module 20a and the second display module 20b. The front-to-back level difference adjustment portion 120 may be disposed spaced apart by a predetermined gap in the up-and-down direction (Y) on the joint surfaces 41 and 42. The joint surfaces 41 and 42 may include a first joint surface 41 provided on a side surface of the first display module 20a, and a second joint surface 42 provided on a side surface of the second display module 20b facing the first joint surface 41.

The front-to-back level difference adjustment portion 120 may include a protrusion 121 protruding from the first joint surface 41, a groove 122 provided on the second joint surface 42 to receive the protrusion 121, and a front-to-back adjustment bolt 123 installed on the protrusion 121. According to an embodiment, the groove 122 may be provided on the first joint surface 41, and the protrusion 121 may be provided on the second joint surface 42.

The protrusion 121 and the groove 122 may be formed in a shape corresponding to each other such that they may engage each other. The protrusion 121 may include a tapered shape with a gradually decreasing cross-sectional area to facilitate entry into the groove 122.

The front-to-back adjustment bolt 123 may be rotatably mounted on the protrusion 121. The protrusion 121 may be provided with a bolt hole 124 into which the front-to-back adjustment bolt 123 is installed. The bolt hole 124 may be formed through the protrusion 121 in the front-to-back direction. Front and rear sides of the bolt hole 124 may be open.

The front-to-back adjustment bolt 123 may be configured to be movable back and forth in the front-to-back direction (Z) in the bolt hole 124 of the protrusion 121. The front-to-back adjustment bolt 123 may be moved back and forth in the front-to-back direction in the bolt hole 124 in accordance with the direction of rotation.

The front-to-back adjustment bolt 123 may be formed in a cylindrical shape to be coupled to the bolt hole 124. The front-to-back adjustment bolt 123 may protrude from a rear opening of the bolt hole 124 when rotated clockwise, and may protrude from a front opening of the bolt hole 124 when rotated counterclockwise.

The front-to-back adjustment bolt 123 may be provided to allow an operator to manipulate the display apparatus 10 from the front. The front of the front-to-back adjustment bolt 123 may be provided with a tool groove 123a for mating a tool for rotational manipulation.

The front-to-back adjustment bolt 123 may have a pitch adjustable in microns to adjust the front-to-back direction level difference of the seam 40. The front-to-back direction (Z) level difference of the seam 40 may be finely adjusted by the front-to-back adjustment bolt 123 protruding from the front opening of the bolt hole 124 or protruding from the rear opening of the bolt hole 124.

According to an embodiment, the gap adjustment portion 110 may further include a stopper member 115 for constraining rotation of the pinion 111.

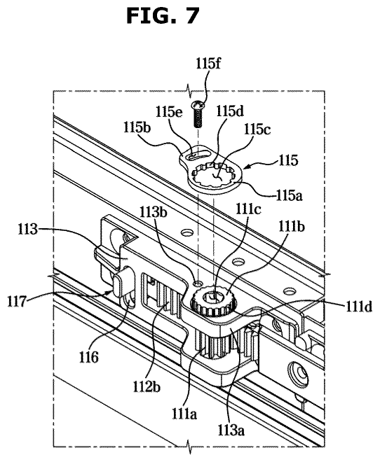

FIG. 7 illustrates a coupling relationship of a stopper member according to an embodiment.

Referring to FIG. 7, the stopper member 115 may prevent backlash of the pinion 111 with the first display module 20a and the second display module 20b in contact via the gap adjustment portion 110.

One side of the stopper member 115 may be engaged with the head portion 111b of the pinion 111 and the other may be fixedly coupled to the first bracket 113.

One side of the stopper member 115 may be provided with a binding portion 115a for engaging with the head portion 111b of the pinion 111, and the other side of the stopper member 115 may be provided with a coupling portion 115b for coupling to the first bracket 113.

The binding portion 115a may include a binding groove 115c into which the head portion 111b of the pinion 111 is inserted and engaged. The binding groove 115c may have a shape that engages with the head portion 111b when the head portion 111b of the pinion 111 is inserted. In an example, when a plurality of catching protrusions 111d are provided along an outer circumferential surface of the head portion 111b, a plurality of catching protrusion receiving grooves 115d corresponding to the plurality of catching protrusions 111d may be provided on an inner circumferential surface of the binding groove 115c. In addition, when the head portion 111b has an elliptical or polygonal shape, the binding groove 115c may be formed in an elliptical or polygonal shape corresponding to the head portion 111b.

The coupling portion 115b may include a fastening slot 115e through which a fastening member 115f passes. The fastening slot 115e may be provided at a position corresponding to a stopper member fixing hole 113b provided on the first bracket 113. The fastening slot 115e may be formed in an arc shape to accommodate changes in an engagement position of the stopper member 115 engaging with the head portion 111b.

The fastening member 115f may pass through the fastening slot 115e and fastened to the stopper member fixing hole 113b to constrain movement of the stopper member 115. Thus, when the stopper member 115 is secured to the first bracket 113, the pinion 111 that engages the stopper member 115 may be constrained from rotating, thereby preventing backlash.

According to an embodiment, the gap adjustment portion 110 may further include a position regulating member 117 to prevent the first display module 20a and the second display module 20b from colliding with each other when they are moved in a direction that brings them closer to each other.

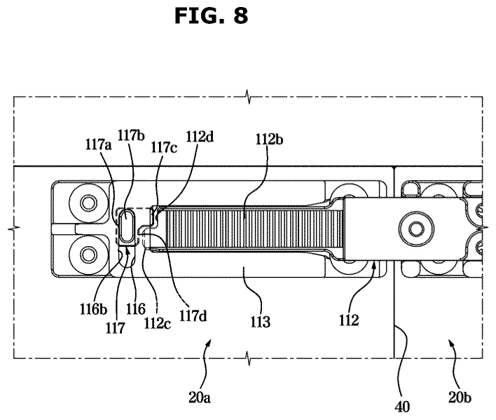

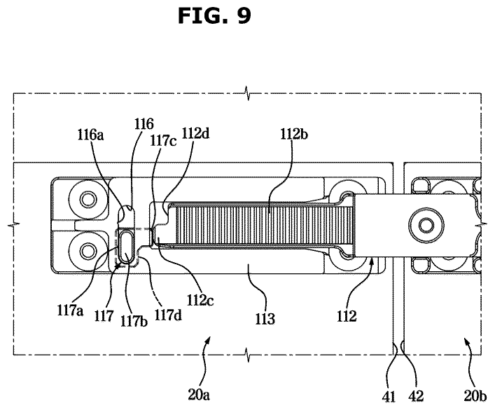

FIG. 8 illustrates a position regulating member in a case where contact of a seam of first and second display modules is allowed according to an embodiment, and FIG. 9 illustrates a position regulating member in a case where contact of the seam of first and second display modules is not allowed according to an embodiment.

Referring to FIGS. 8 and 9, the position regulating member 117 may prevent contact of the seam 40 of the first and second display modules 20a and 20b by regulating a movement range of the rack gear 112. The position regulating member 117 may restrict movement of the first and second display modules 20a and 20b by contacting the rack gear 112 while the rack gear 112 moves to a first position that brings the seams 40 of the first and second display modules 20a and 20b into close contact with each other, as shown in FIG. 9.

The position regulating member 117 may be installed to be slidable up and down on the first bracket 113. The position regulating member 117 may move in the up-and-down direction along a guide slot 116 provided in the first bracket 113.

The guide slot 116 may be formed to extend a predetermined length in the up-and-down direction. The position regulating member 117 may be fixed in a position at an upper portion or a lower portion of the guide slot 116. One side of the position regulating member 117 may be provided with a protruding stopper protrusion 117a.

The stopper protrusion 117a of the position regulating member 117 may be inserted into and caught by a stopper groove 116a or 116b provided on sides of the guide slot 116 while moving along the guide slot 116. The stopper groove 116a and 116b may include an upper stopper groove 116a for fixing the position regulating member 117 at an upper portion of the guide slot 116, and a lower stopper groove 116b for fixing the position regulating member 117 at a lower portion of the guide slot 116.

When the position regulating member 117 is positioned at the upper portion of the guide slot 116, it may be defined as a non-contact position, and when the position regulating member 117 is positioned at the lower portion of the guide slot 116, it may be defined as a contact position.

In the non-contact position, the position regulating member 117 may not contact an end portion of the rack gear 112 until it moves to the first position where the seams 40 of the first and second display modules 20a and 20b are in contact, as shown in FIG. 8. In the contact position, the position regulating member 117 may contact the end portion of the rack gear 112 while moving to the first position where the seams 40 of the first and second display modules 20a and 20b are contacted, as shown in FIG. 9.

The position regulating member 117 may include a movable body portion 117b that moves along the guide slot 116. A first contact protrusion portion 117c and a first step portion 117d may be provided on a side of the movable body portion 117b. The first contact protrusion portion 117c may extend by a predetermined length in a transverse direction from the movable body portion 117b toward the rack gear 112.

A second contact protrusion portion 112c and a second step portion 112d may be provided at the end portion of the rack gear 112 facing the position regulating member 117. The second contact protrusion portion 112c may extend by a predetermined length in the transverse direction toward the position regulating member 117.

When the position regulating member 117 is positioned in the non-contact position as shown in FIG. 8, the first contact protrusion portion 117c and the second contact protrusion portion 112c may be disposed facing the second step portion 112d and the first step portion 117d, respectively, so that the end portion of the rack gear 112 may not be in contact with the position regulating member 117 until the seam 40 is in contact. On the other hand, when the position regulating member 117 is positioned in the contact position as shown in FIG. 9, the first contact protrusion portion 117c and the second contact protrusion portion 112c come into contact with each other, so that the seam 40 may be spaced apart.

According to an embodiment, the level difference adjustment portion 100 may include a up-and-down level difference adjustment portion 130 for adjusting the up-and-down (i.e., vertical) direction (Y) level difference of the first display module 20a and the second display module 20b.

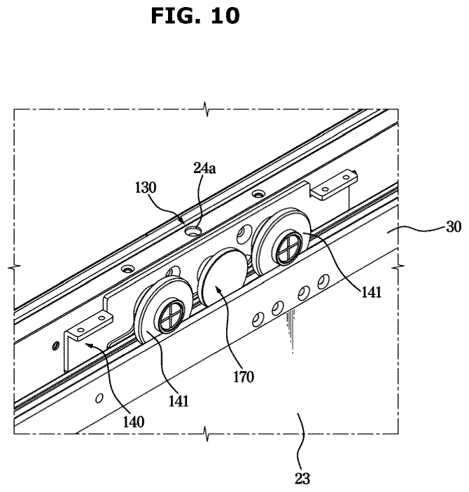

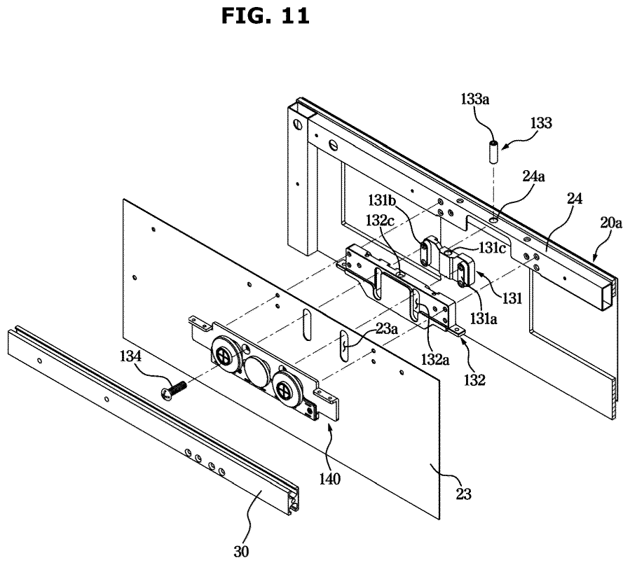

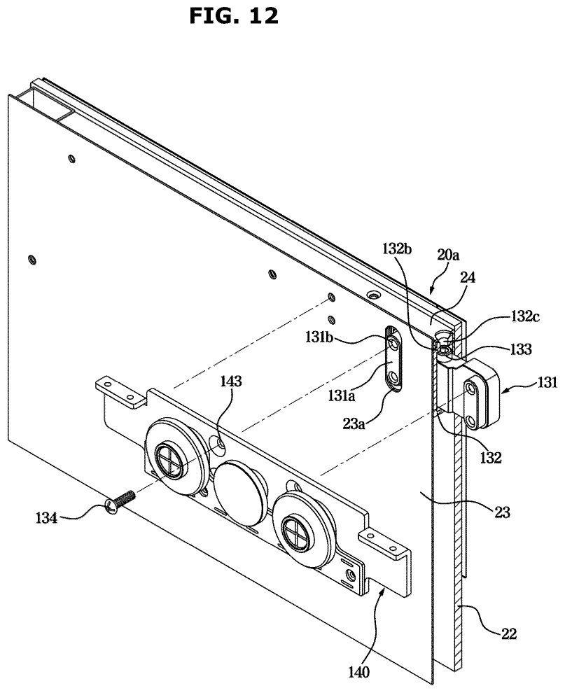

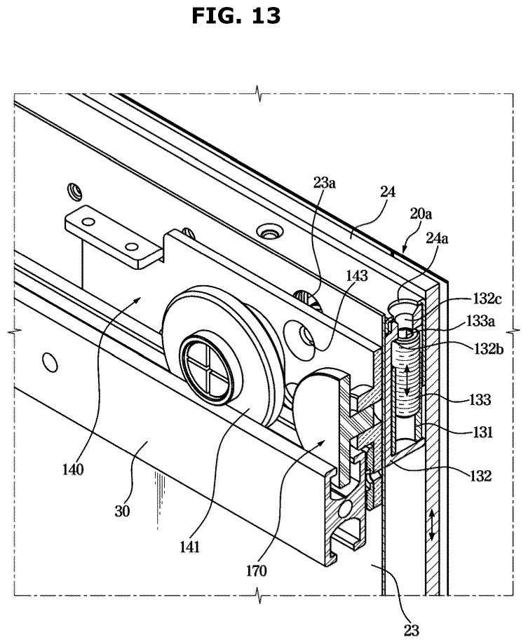

FIG. 10 is a perspective view illustrating an up-and-down level difference adjustment portion according to an embodiment, FIG. 11 is an exploded perspective view of the up-and-down level difference adjustment portion according to an embodiment, FIG. 12 is a partially cutaway view of the up-and-down level difference adjustment portion according to an embodiment, and FIG. 13 is a view illustrating an operational state of the up-and-down level difference adjustment portion according to an embodiment.

Referring to FIGS. 10 to 13, the first display module 20a and the second display module 20b may each include a wheel unit 140 to which a wheel 141 that moves along the rail frame 30 is coupled.

The wheel unit 140 may be coupled to the rear cover 23 of the display modules 20a and 20b. The wheel unit 140 may be positioned on an upper portion of the rear cover 23. A plurality of wheel units 140 may be provided on each of the display modules 20a and 20b. As shown in FIG. 2, two wheel units 140 may be disposed on each of the display modules 20a and 20b at a predetermined interval in the left-to-right direction (X).

The up-and-down level difference adjustment portion 130 may move the display modules 20a and 20b in the vertical direction while the wheel unit 140 is seated on the rail frame 30. To this end, the wheel unit 140 may be movably coupled relative to the display modules 20a and 20b in the vertical direction. The wheel unit 140 may be movably coupled relative to the rear cover 23 of the display modules 20a and 20b. In other words, the up-and-down level difference adjustment portion 130 may move the display modules 20a and 20b relative to the wheel unit 140 in the vertical direction.

The up-and-down level difference adjustment portion 130 may include a connection member 131, a guide member 132, and an up-and-down adjustment bolt 133.

The connection member 131 may be integrally connected to the wheel unit 140. The connection member 131 may be movably disposed relative to the display modules 20a and 20b inside the display modules 20a and 20b.

The connection member 131 may be integrally connected to the wheel unit 140 via a fastening member 134. The fastening member 134 may pass through a cover slot 23a of the rear cover 23 and be fastened to the connection member 131. The cover slot 23a of the rear cover 23 may be elongated in the vertical direction to allow for vertical movement of the fastening member 134. Thus, the connection member 131 and the wheel unit 140, which are integrally connected via the fastening member 134, may be moved together relative to the display modules 20a and 20b.

The guide member 132 may be fixedly installed inside the display modules 20a and 20b. The guide member 132 may be fixedly installed on the reinforcing frame 24. The connection member 131 may be slidably supported in the vertical direction inside the guide member 132.

The guide member 132 may be provided with a connection member guide slot 132a extending in the vertical direction to guide sliding movement of the connection member 131. The connection member guide slots 132a may be provided in pairs for stable movement of the connection member 131.

The connection member 131 may be provided with a guide protrusion 131a that moves along the connection member guide slot 132a. The guide protrusions 131a may be provided in pairs corresponding to the connection member guide slot 132a. The connection member guide slot 132a may be provided with a longer length r in the vertical direction than the guide protrusion 131a to allow the guide protrusion 131a to move up and down along the connection member guide slot 132a.

The rear cover 23 may have a cover slot 23a formed therethrough that corresponds to the connection member guide slot 132a. The guide protrusion 131a provided on the connection member 131 may be exposed to an outside of the rear cover 23 through the cover slot 23a. The cover slot 23a may have a length corresponding to a vertical length of the connection member guide slot 132a.

The guide protrusion 131a may be provided with a guide protrusion fastening hole 131b for connection with the wheel unit 140. The guide protrusion fastening holes 131b may be disposed in tow locations, at an upper portion and a lower portion of the guide protrusion 131a. The fastening member 134 may integrally connect the wheel unit 140 and the connection member 131 by sequentially passing through the wheel unit 140, the cover slot 23a, the connection member guide slot 132a, and then being fastened to the guide protrusion fastening hole 131b.

The up-and-down adjustment bolt 133 may move in the up-and-down direction (Y) in the connection member 131. The up-and-down adjustment bolt 133 may move up and down in the connection member 131 when rotated clockwise or counterclockwise. The connection member 131 may include a bolt hole 131c to which the up-and-down adjustment bolt 133 is fastened. The bolt hole 131c may be located between a pair of guide protrusions 131a provided on the connection member 131.

When the up-and-down adjustment bolt 133 is moved upward by rotational operation, the up-and-down adjustment bolt 133 may lift the display modules 20a and 20b upwardly with respect to the connection member 131. To this end, the up-and-down adjustment bolt 133 may be positioned between the connection member 131 and the guide member 132. The up-and-down adjustment bolt 133 be movable in the up-and-down direction between the connection member 131 and the guide member 132.

An upper end of the up-and-down adjustment bolt 133 may be positioned in a state of being in contact with the guide member 132. The guide member 132 may include a stepped portion 132b that contacts the upper end of the up-and-down adjustment bolt 133. The guide member 132 may include a tool insertion hole 132c into which a tool, such as a wrench, is inserted. The operator may couple the tool to a wrench groove 133a of the up-and-down adjustment bolt 133 through the tool insertion hole 132c. An opening 24a may be formed on the reinforcing frame 24 at a position corresponding to the tool insertion hole 132c.

As shown in FIG. 13, when the up-and-down adjustment bolt 133 is rotated and moved upward, the display modules 20a and 20b integrally connected to the guide member 132 may be moved upward by pushing the guide member 132 upward. Conversely, when the up-and-down adjustment bolt 133 is moved downward, the guide member 132 supported by the up-and-down adjustment bolt 133 may also be moved downward due to its own weight, so that the display modules 20a and 20b integrally connected to the guide member 132 may be moved downward. Accordingly, the up-and-down movement of the display modules 20a and 20b may not affect the wheel unit 140 supported by the rail frame 30, thereby preventing the wheel unit 140 from lifting from the rail frame 30 during vertical level difference adjustment of the display modules 20a and 20b.

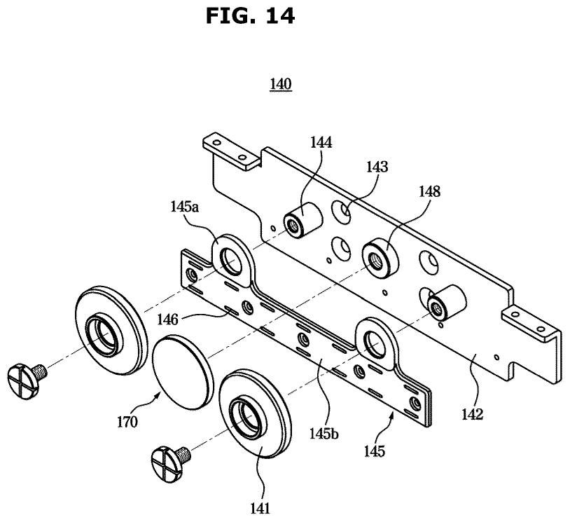

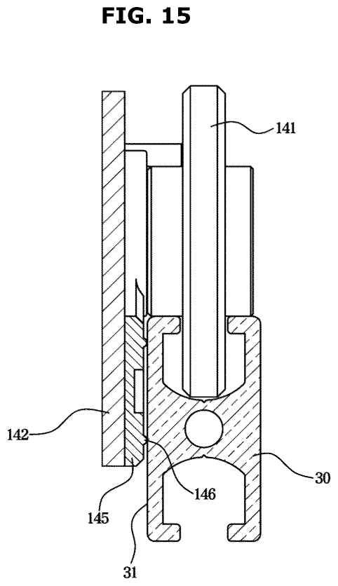

FIG. 14 is an exploded perspective view of a wheel unit according to an embodiment, and FIG. 15 is a cross-sectional view of the wheel unit according to an embodiment.

Referring to FIGS. 14 and 15, the wheel unit 140 may include a wheel bracket 142 on which the wheel 141 that moves along the rail frame 30 is installed.

The wheel bracket 142 may be movably coupled to the rear surface of the rear cover 23 in the up-and-down direction, as shown in FIG. 13. The wheel bracket 142 may include a plurality of fastening holes 143 through which the fastening members 134 for bolting to the connection member 131 may pass. The plurality of fastening holes 143 may be positioned in corresponding positions to the cover slots 23a.

The wheel bracket 142 may include a pair of shaft support portions 144 to which a plurality of wheels 141 are rotatably coupled.

The wheel bracket 142 may include a friction reducing member 145 for reducing contact friction resistance with the rail frame 30. The friction reducing member 145 may be coupled to a rear surface of the wheel bracket 142.

The friction reducing member 145 may reduce frictional forces generated upon contact with the rail frame 30 by contacting one surface 31 of the rail frame 30 during movement of the wheel unit 140 along the rail frame 30.

The friction reducing member 145 may include a material with a low coefficient of friction. In an example, the friction reducing member 145 may include a lubricious synthetic resin material or a lubricious alloy material. The friction reducing member 145 may include polyacetal.

The friction reducing member 145 may include a wheel support portion 145a that contacts the wheel 141 around the shaft support portion 144, and a rail frame support portion 145b that contacts the one surface 31 of the rail frame 30.

The wheel support portion 145a may reduce frictional forces generated during rotation of the wheel 141 by contacting the wheels 141, and the rail frame support portion 145b may reduce friction resistance with the rail frame 30 by contacting the one surface 31 of the rail frame 30.

According to an embodiment, the rail frame support portion 145b may include friction reducing protrusions 146 to reduce the area of friction with the rail frame 30.

The friction reducing protrusions 146 may be provided in a shape that protrudes from the rail frame support portion 145b toward the rail frame 30 so as to be line contact or point contact with the one surface 31 of the rail frame 30. The friction reducing protrusion 146 of the present disclosure are shown in the form of ribs that may be in line contact with the one surface 31 of the rail frame 30, but may include a hemispherical shape.

The friction reducing protrusion 146 may be spaced apart from the rail frame support portion 145b by predetermined intervals. The friction reducing protrusions 146 may extend by a predetermined length along a longitudinal direction of the rail frame 30, i.e., the left-to-right direction (X). The friction reducing protrusions 146 may be disposed spaced apart at predetermined intervals in the up-and-down direction and the left-to-right direction from the rail frame support portion 145b for stable support.

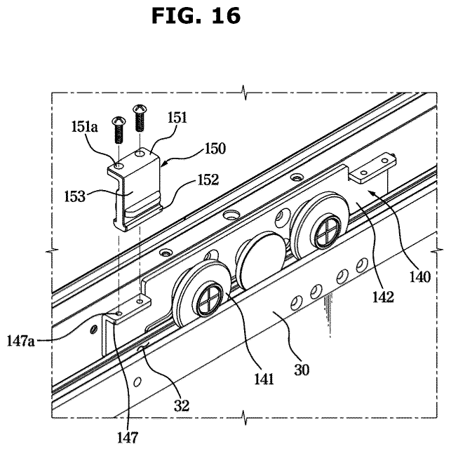

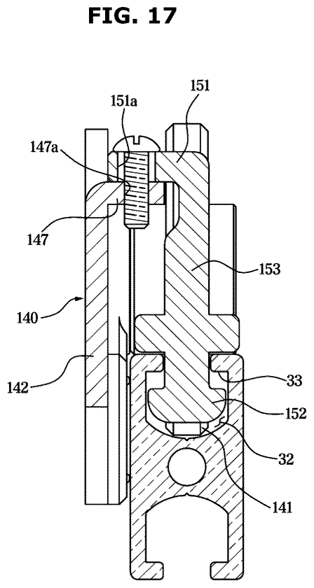

FIG. 16 is a view illustrating an anti-separation member according to an embodiment, and FIG. 17 illustrates a cross-sectional view of the anti-separation member coupled to the wheel unit according to an embodiment.

Referring to FIGS. 16 and 17, the wheel unit 140 may include an anti-separation member (or anti-lift member) 150 for preventing the display modules 20a and 20b from deviating from the rail frame 30 when lifted upward.

The anti-separation member 150 may be positioned with one side coupled to and fixed to the wheel unit 140 and the other side received in a rail groove 32 of the rail frame 30. The wheel unit 140 may include a coupling flange 147 having a fastening hole 147a for coupling with the anti-separation member 150. The coupling flange 147 may be provided at each of the left and right ends of the wheel unit 140.

The anti-separation member 150 may include a coupling portion 151, a catch portion 152, and a connection portion 153 connecting the coupling portion 151 and the catch portion 152.

The coupling portion 151 may be formed in a horizontal panel shape extending in a horizontal direction to be coupled to the wheel unit 140. A plurality of bolting holes 151a for bolting with the wheel unit 140 may be provided on the coupling portion 151.

The connection portion 153 may be formed in a vertical panel shape bent from an end of the coupling portion 151 and extending downwardly. A lower end of the connection portion 153 may have a cross-sectional thickness that may enter the rail groove 32 of the rail frame 30.

The catch portion 152 may be formed in a hook shape having a larger cross-sectional area than the connection portion 153 at an end of the connection portion 153. The catch portion 152 may be provided in a protruding form from the end of the connection portion 153 in both lateral directions, i.e., toward the front and the rear.

The catch portion 152 may have a height lower than a height of the rail groove 32 so as to be movable in the up-and-down direction within the rail groove 32. This is to allow the up-and-down level difference adjustment of the display modules 20a and 20b even when the anti-separation member 150 is installed on the wheel unit 140.

The catch portion 152 may be caught and supported by a locking step 33 located on an upper portion of the rail groove 32 when lifted upwardly in a state of being received in the rail groove 32. Thus, when the wheel unit 140 is lifted, the wheel unit 140 may be prevented from deviating from the rail frame 30.

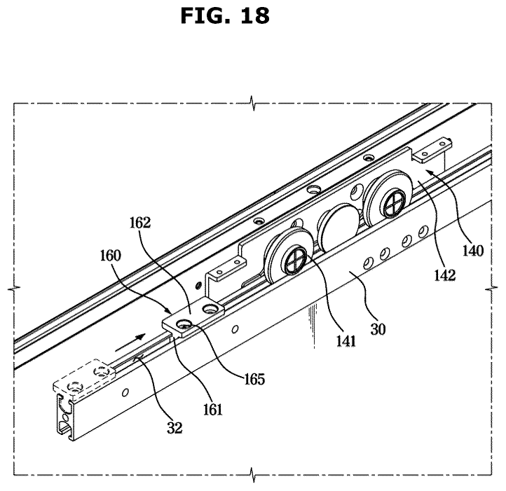

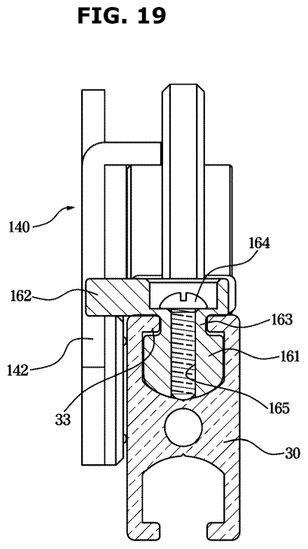

FIG. 18 illustrates a travel stopper installed on a rail frame according to an embodiment, and FIG. 19 illustrates a cross-section of the travel stopper coupled to the rail frame according to an embodiment.

Referring to FIGS. 18 and 19, the display apparatus 10 may include a travel stopper 160 that may restrict movement of the wheel unit 140 in the left-to-right direction (X) on the rail frame 30.

The travel stopper 160 may be movable in the left-to-right direction along the rail groove 32 of the rail frame 30, and may constrain the movement of the wheel unit 140 as it is positioned on the rail frame 30 in contact with the wheel unit 140.

The travel stopper 160 may include a slider body 161 that moves along the rail groove 32 of the rail frame 30. The slider body 161 may have a cross-sectional shape corresponding to the rail groove 32.

The travel stopper 160 may include a support plate 162 provided on an upper portion of the slider body 161. The support plate 162 may contact one side of the wheel unit 140 during movement of the travel stopper 160 along the rail frame 30. A lower surface of the support plate 162 may be slidably movable in close contact with an upper surface of the rail frame 30.

The travel stopper 160 may include a neck portion 163 positioned between the slider body 161 and the support plate 162. The neck portion 163 may be positioned in a space between locking steps 33 facing each other on the rail frame 30.

The travel stopper 160 may be secured in position on the rail frame 30 by a fastening member 164. The travel stopper 160 may have a fastening hole 165 formed penetrating in the up-and-down direction. The fastening hole 165 may be provided in pairs in the travel stopper 160. The fastening member 164 may constrain movement of the travel stopper 160 by passing through the fastening hole 165 and being fastened to a bottom of the rail groove 32.

The travel stopper 160 may be used to change a viewing position of the display apparatus 10 after the display apparatus 10 is installed on the rail frame 30. For example, the viewing position may be changed by moving the display apparatus 10 while repositioning the travel stopper 160 on the rail frame 30. In addition, the travel stopper 160 may be used to adjust the level difference of the display apparatus 10. For example, in a state in which the position of the first display module 20a on the rail frame 30 is first set, the level difference between the first display module 20a and the second display module 20b may be adjusted through the level difference adjustment portion 100 while the movement of the first display module 20a in one direction is fixed using the travel stopper 160.

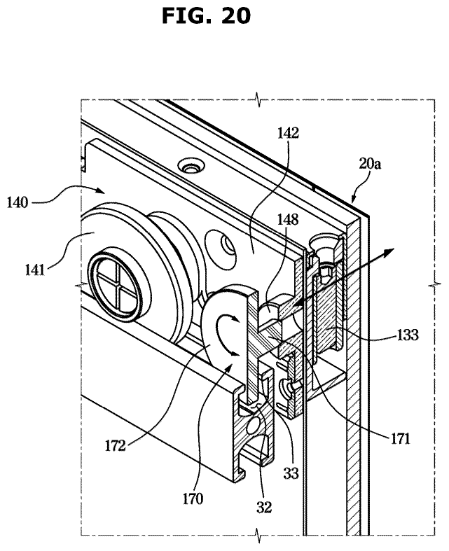

FIG. 20 illustrates a front-to-back adjustment member according to an embodiment.

Referring to FIGS. 14 and 20, the wheel unit 140 may include a front-to-back adjustment member 170 for moving the corresponding display modules 20a and 20b in the front-to-back direction relative to the rail frame 30.

The front-to-back adjustment member 170 may be disposed between the pair of wheels 141. The front-to-back adjustment member 170 may be disposed at a position corresponding to the up-and-down adjustment bolt 133 between the pair of wheels 141. This may increase efficiency of the level difference adjustment operation of the display apparatus 10.

The front-to-back adjustment member 170 may include a screw shaft portion 171 and an operation head portion 172 for rotationally operating the screw shaft portion 171.

The screw shaft portion 171 may be screw-coupled to a boss 148 provided on the wheel bracket 142.

The operation head portion 172 may be positioned with a portion thereof received in the rail groove 32 of the rail frame 30. In other words, a portion of the operation head portion 172 may be positioned between the locking steps 33 facing each other on the rail frame 30.

The front-to-back adjustment member 170 may finely move the corresponding display modules 20a and 20b in the front-to-back direction. When the front-to-back adjustment member 170 is rotated in one direction, the corresponding display modules 20a and 20b may be moved away from the rail frame 30, and when the front-to-back adjustment member 170 is rotated in the other direction, the corresponding display modules 20a and 20b may be moved closer to the rail frame 30.

The display apparatus 10 according to an embodiment includes the level difference adjustment portion 100 configured to adjust a level difference between the first display module 20a and the second display module 20b adjacent to each other, and the level difference adjustment portion includes the gap adjustment portion 110 configured to move a seam, at which the first display module 20a and the second display module 20b are in contact, between a first position for close contact and a second position for spacing apart, in response to direction of rotation of the pinion 111 engaging with the rack gear 112, and the front-to-back level difference adjustment portion 120 configured to adjust a front-to-back direction level difference of the seam 40. According to the present disclosure, an operator may easily perform a level difference adjustment operation of divided display modules.

The front-to-back level difference adjustment portion may be provided on joint surfaces 41 and 42 of the first and second display modules so as to be concealed when the first and second display modules are in contact, and be exposed to an outside when the first and second display modules are moved away from each other. According to the present disclosure, an exterior aesthetic of the display apparatus 10 may be excellent.

The front-to-back level difference adjustment portion 120 may include the protrusion 121 protruding from the first joint surface 41 of the first display module 20a toward the second joint surface 42 of the second display module 20b facing the first joint surface, and on which the front-to-back adjustment bolt 123 is provided, and the groove 122 recessed in the second joint surface 42 to receive the protrusion 121.

The pinion 111 may be rotatably installed on the first bracket 113 installed on the first display module, and one side of the rack gear may be fixedly installed on the second bracket 114 installed on the second display module, and the other side may extend toward the pinion and engage with the pinion.

The gap adjustment portion 110 may further include the stopper member 115 configured to constrain rotation of the pinion. According to the present disclosure, stable position fixation may be possible by preventing backlash of the pinion after level difference adjustment of the display apparatus.

The pinion 111 may include the shaft portion 111a having gear teeth engaging with the rack gear 112, and the head portion 111b configured for rotational operation of the pinion, and the gap adjustment portion may further include the stopper member 115, the stopper member having one side engaged and coupled to the head portion 111b and the other side coupled to the first bracket.

The gap adjustment portion 110 may further include the position regulating member 117 configured to regulate a movement range of the rack gear 112 moving toward the first position. According to the present disclosure, damage due to collision of the first and second display modules 20a and 20b may be prevented when moving to bring the first display module 20a and the second display module 20b into contact.

The position regulating member 117 may be configured to be movable between: a contact position in which the position regulating member contacts the rack gear 112 while moving to the first position at which the first and second display modules 20a and 20b are in contact, and a non-contact position in which the position regulating member does not contact the rack gear 112 until the position regulating member moves to the first position at which the first and second display modules 20a and 20b are in contact.

The level difference adjustment portion 100 may further include the up-and-down level difference adjustment portion 130 configured to adjust an up-and-down direction level difference of the first and second display modules 20a and 20b.

Each of the first display module 20a and the second display module 20b may include the wheel unit 140 configured to move along the rail frame 30 installed on a wall, the wheel unit may be movably coupled relative to the corresponding display modules 20a and 20b in the up-and-down direction, and the up-and-down level difference adjustment portion 130 may include the up-and-down adjustment bolt 133 configured to move the corresponding display modules 20a and 20b in the up-and-down direction relative to the wheel unit 140 when tightened or loosened. According to the present disclosure, the up-and-down level difference adjustment of the display module may be possible while the display module is supported on the rail frame.

The up-and-down level difference adjustment portion 130 may include the connection member 131 positioned inside the corresponding display modules 20a and 20b and to which the up-and-down adjustment bolt 133 is movably coupled in the up-and-down direction, and the connection member may be connected to the wheel unit and configured to move together with the wheel unit relative to the corresponding display modules 20a and 20b.

The wheel unit 140 may include the wheel bracket 142 on which the wheel 141 that moves along the rail frame is installed, and the friction reducing member 145 coupled to the wheel bracket to reduce contact friction resistance with the rail frame during movement of the wheel unit. According to the present disclosure, stable movement of the display apparatus on the rail frame may be possible.

The friction reducing member 145 may include the friction reducing protrusion 146 protruding to contact the rail frame.

The wheel unit 140 may further include the anti-separation member 150 configured to prevent the wheel unit 140 from deviating from the rail frame 30 when lifted upward, and one side of the anti-separation member 150 may be secured to the wheel unit 140, and the other side may be configured to be caught by the locking step 33 on an upper portion of the rail groove 32 when lifted upward in a state of being received in the rail groove 32 of the rail frame 30.

The up-and-down level difference adjustment portion 130 may further include the guide member 132 secured to the corresponding display modules 20a and 20b to guide sliding movement of the connection member 131 and on which the connection member 131 is slidably supported.

The display apparatus may further include the travel stopper 160 configured to restrict a left-right movement of the wheel unit 140 relative to the rail frame 30, and the travel stopper 160 may be movable along the rail groove 32 of the rail frame 30, and may be fixed to the rail frame 30 by a fastening bolt passing through the travel stopper 160 and fastened to the rail groove 32.

The wheel unit 140 may further include the front-to-back adjustment member 170 configured to move the corresponding display modules 20a and 20b in the front-to-back direction relative to the rail frame 30.

A display apparatus according to an embodiment may include the pair of rail frames 30 installed on a wall spaced apart vertically, the first display module 20a and the second display module 20b movably supported on the pair of rail frames and contactable with each other, and the level difference adjustment portion 100 configured to adjust a level difference between the first display module and the second display module, wherein the level difference adjustment portion includes the gap adjustment portion 110 configured to adjust a gap between the seams 40 where the first display module and the second display module are in contact, and the gap adjustment portion includes the rack gear 112 provided on the first display module, and the pinion 111 provided on the second display module to engage with the rack gear and which, depending on a direction of rotation, brings the first display module and the second display module into contact or further apart.

The level difference adjustment portion 100 may further include the front-to-back level difference adjustment portion 120 provided on the joint surfaces 41 and 42 where the first display module 20a and the second display module 20b are in contact, so as to be exposed to an outside when a gap of the seam increases.

Each of the first display module 20a and the second display module 20b may include the wheel unit 140 configured to move along the pair of rail frames 30, and the level difference adjustment portion may further include the up-and-down level difference adjustment portion 130 configured to move the corresponding display module relative to the wheel unit supported by the rail frame in the up-and-down direction.

According to the spirit of the present disclosure, work convenience may be improved by facilitating the level difference adjustment operation during installation of divided display modules.

According to the spirit of the present disclosure, damage to the seam of the display module due to collision may be prevented when moving the divided display modules.

According to the spirit of the present disclosure, stable level difference adjustment may be possible while the display apparatus is seated on the rail frame.

According to the spirit of the present disclosure, unexpected deviation of the display apparatus from a rail frame may be prevented.

The effects to be obtained from the present disclosure are not limited to those mentioned above, and other effects not mentioned will be apparent to those of skilled in the art from the following description.

Although the above technical ideas of the disclosure have been described by way of specific embodiments, the scope of the disclosure is not limited to these embodiments. Various modifications and variations that can be made by those skilled in the art without departing from the technical ideas of the disclosure as set forth in the claims of the patent will be deemed to be within the scope of the disclosure.

1. A display apparatus, comprising:
a level difference adjustment portion configured to adjust a level difference between a first display module and a second display module adjacent to each other,
wherein the level difference adjustment portion comprises:
a gap adjustment portion configured to move a seam, along which the first display module and the second display module are in contact with each other, between a first position while the first display module and the second display module are brought into close contact with each other and a second position in which the seam are spaced apart from each other, based on a direction of rotation of a pinion engaging with a rack gear; and
a front-to-back level difference adjustment portion configured to adjust a front-to-back direction level difference of the seam.

2. The display apparatus of claim 1, wherein the front-to-back level difference adjustment portion is on a joint surface of the first display module and the second display module so as to be concealed while the first display module and the second display module are in contact, and be exposed to an outside while the first display module and the second display module are moved away from each other.

3. The display apparatus of claim 1, wherein the front-to-back level difference adjustment portion comprises:
a protrusion protruding from a first joint surface of the first display module toward a second joint surface of the second display module facing the first joint surface, and on which a front-to-back adjustment bolt is provided; and
a groove recessed in the second joint surface to receive the protrusion.

4. The display apparatus of claim 1, wherein
the pinion is rotatably installed on a first bracket installed on the first display module, and
one side of the rack gear is fixedly installed on a second bracket which is installed on the second display module, and another side of the rack gear extends toward the pinion and engages with the pinion.

5. The display apparatus of claim 1, wherein the gap adjustment portion further comprises a stopper member configured to constrain a rotation of the pinion.

6. The display apparatus of claim 4, wherein
the pinion comprises a shaft portion having gear teeth engaging with the rack gear, and a head portion configured to rotationally operate the pinion, and
the gap adjustment portion further comprises a stopper member, the stopper member having one side engaged and coupled to the head portion and another side coupled to the first bracket.

7. The display apparatus of claim 1, wherein the gap adjustment portion further comprises a position regulating member configured to regulate a movement range of the rack gear moving toward the first position.

8. The display apparatus of claim 7, wherein the position regulating member is configured to be movable between:
a contact position in which the position regulating member contacts the rack gear while the first display module and the second display module move to the first position at which the first display module and the second display module are in contact with each other, and
a non-contact position in which the position regulating member is prevented from contacting the rack gear until the first display module and the second display module move to the first position at which the first display module and the second display module are in contact with each other.

9. The display apparatus of claim 1, wherein the level difference adjustment portion further comprises an up-and-down level difference adjustment portion configured to adjust an up-and-down direction level difference of the first display module and the second display module.

10. The display apparatus of claim 9, wherein
the first display module and the second display module respectively comprise a wheel unit configured to move along a rail frame installed on a wall,
the wheel unit is coupled to a corresponding display module to be relatively movable along the up-and-down direction, and
the up-and-down level difference adjustment portion comprises an up-and-down adjustment bolt configured to move the corresponding display module along the up-and-down direction relative to the wheel unit when tightened or loosened.

11. The display apparatus of claim 10, wherein
the up-and-down level difference adjustment portion comprises a connection member positioned inside the corresponding display module and to which the up-and-down adjustment bolt is movably coupled along the up-and-down direction, and
the connection member is connected to the wheel unit and configured to move relative to the corresponding display module together with the wheel unit.

12. The display apparatus of claim 10, wherein the wheel unit comprises:
a wheel bracket on which a wheel configured to move along the rail frame is installed; and
a friction reducing member coupled to the wheel bracket to reduce contact friction resistance with the rail frame during movement of the wheel unit.

13. The display apparatus of claim 12, wherein the friction reducing member comprises a friction reducing protrusion protruding to contact the rail frame.

14. The display apparatus of claim 10, wherein
the wheel unit further comprises an anti-separation member configured to prevent the wheel unit from deviating from the rail frame when lifted upward, and
one side of the anti-separation member is secured to the wheel unit, and another side is configured to be caught by a locking step on an upper portion of a rail groove when lifted upward in a state of being received in the rail groove of the rail frame.

15. The display apparatus of claim 11, wherein the up-and-down level difference adjustment portion further comprises a guide member secured to the corresponding display module to guide sliding movement of the connection member and on which the connection member is slidably supported.
